(19) United States
(12) Patent Application Publication
(10) Pub. No.: US 2008/0277155 A1
(43) Pub. Date: Nov. 13, 2008

(54) Wiring substrate and method of manufacturing the same

(75) Inventor: Akio Horiuchi, Nagano (JP)

Correspondence Address: KRATZ, QUINTOS & HANSON, LLP, 1420 K Street, N.W., Suite 400, WASHINGTON, DC, 20005, US

(73) Assignee: SHINKO ELECTRIC INDUSTRIES CO., LTD., Nagano-shi (JP)

(21) Appl. No.: 12/078,514

(22) Filed: Apr. 1, 2008

(30) Foreign Application Priority Data
May 8, 2007 (JP) 2007-123154

(51) Int. Cl. H05K 1/00; H05K 3/10

(52) U.S. Cl. 174/264; 29/846

(57) ABSTRACT

In a method of manufacturing a wiring substrate of the present invention, a through-hole plating layer is formed from an inner surface of a through hole in a substrate to both surface sides, then a resin is filled in a through hole, and then a first resist in which an opening portion is provided on the through hole is formed. Then, a partial cover plating layer is formed in the opening portion in the first resist, then the first resist is removed, and then a second resist that covers a whole of the partial cover plating layer and has a pattern for patterning the through-hole plating layer is formed. Then, a pad wiring portion containing the partial cover plating layer and a wiring pattern are obtained by etching the through-hole plating layer while using the second resist as a mask.

### CROSS-REFERENCE TO RELATED APPLICATIONS

This application is based on and claims priority of Japanese Patent Application No. 2007-123154 filed on May 8, 2007, the entire contents of which are incorporated herein by reference.

### BACKGROUND OF THE INVENTION

1. Field of the Invention

The present invention relates to a wiring substrate and a method of manufacturing the same and, more particularly, a wiring substrate applicable to a mounting substrate of electronic components and a method of manufacturing the same.

2. Description of the Related Art

In recent years, with the progress of electronic equipments, miniaturization/higher-functionalization are demanded of the wiring substrate on which the electronic components are mounted. As the wiring substrate, there is the printed wiring board having such a structure that the wiring patterns connected mutually via the through hole plating layers, which are provided in the through holes in the substrate, are formed on both surface sides of the substrate.

In the method of manufacturing such printed wiring board, as shown in FIG. 1A, first, a resin substrate 100 on both surfaces of which a copper foil 200 is pasted is processed by the drilling to form a through hole TH. Then, as shown in FIG. 1B, a through-hole plating layer 300 is formed on an inner surface of the through hole TH and the copper foil 200 on both surface sides.

Then, as shown in FIG. 1C, a hole filling resin 400 is filled in the through hole TH. Then, as shown in FIG. 1D, a cover plating layer 500 is formed on the through-hole plating layer 300 and the hole filling resin 400 on both surface sides on the resin substrate 100 respectively.

Then, as shown in FIG. 1E, a resist pattern 600 is formed on the cover plating layer 500 on both surface sides on the resin substrate 100 respectively. Then, as shown in FIG. 1F, the cover plating layer 500, the through-hole plating layer 300, and the copper foil 200 are wet-etched by a chemical solution using the resist pattern 600 as a mask. Then, the resist pattern 600 is removed.

Accordingly, as shown in FIG. 1G, a wiring pattern 700 composed of the copper foil 200, the through-hole plating layer 300, and the cover plating layer 500 is formed on both surface sides on the resin substrate 100 respectively. The wiring patterns 700 arranged on and under the through hole TH functions as a through-hole pad, and are connected mutually via the through-hole plating layer 300. Then, predetermined wiring patterns connected to the wiring pattern 700 are stacked on both surface sides on the resin substrate 100, and thus the printed wiring board is manufactured.

The method of manufacturing the printed wiring board as described above is set forth in Patent Literature 1 (Patent Application Publication (KOKAI) 2001-144397).

Also, in Patent Literature 21 (Patent Application Publication (KOKAI) 2005-268633), the method of sealing the through hole in the printed wiring board is set forth. More particularly, it is set forth that the filling material is filled in the through hole like a rivet and is cured, and the abrasive is sprayed to the rivet portion by the high-pressure injection system, and thus the rivet portion is reduced in size and removed.

In the above method of manufacturing the printed wiring board in the prior art, in circumstances of arrangement of the pads on the through hole TH, the cover plating layer 500 is formed on the through-hole plating layer 300 over the whole surface of the resin substrate 100. Therefore, in the steps of forming the wiring pattern 700 (FIG. 1E and FIG. 1F), the copper layer which is a thick film whose thickness is 20 to 30 μm thickness, for example, composed of the cover plating layer 500, the through-hole plating layer 300 and the copper foil 200 must be etched by the isotropic wet etching.

Therefore, the wiring pattern 700 is shifted considerably to the inner side than the resist pattern 600 by the etching and is formed narrowly. As a result, the design specification for a line width cannot be satisfied upon forming the finer wiring patterns, and thus such a problem exists that these wirings cannot respond to the miniaturization of the wiring patterns.

### SUMMARY OF THE INVENTION

It is an object of the present invention to provide a method of manufacturing a wiring substrate capable of forming fine wiring patterns, and a wiring substrate.

The present invention relates to a method of manufacturing a wiring substrate, and includes the steps of forming a through hole in a substrate; forming a through-hole plating layer from an inner surface of the through hole to both surface sides of the substrate; filling a resin in the through hole; forming a first resist, in which an opening portion is provided on the through hole and its neighborhood, on both surface sides of the substrate respectively; forming a partial cover plating layer connected to the through-hole plating layer in the opening portion of the first resist by a plating; removing the first resist; forming a second resist, which covers a whole of the partial cover plating layer and has a pattern for patterning the through-hole plating layer, on both surface sides of the substrate respectively; and forming a pad wiring portion, which is composed of the through-hole plating layer and the partial cover plating layer and connected mutually via the through-hole plating layer, and a wiring pattern, which is formed of the through-hole plating layer and separated from the pad wiring portion, on both surface sides of the substrate respectively, by etching the through-hole plating layer while using the second resist as a mask.

In the method of manufacturing the wiring substrate of the present invention, first, the through hole is formed in the substrate, then the through-hole plating layer is formed to extend from an inner surface of the through hole to both surface sides of the substrate, and then the resin is filled in the through hole. Then, the first resin in which the opening portion is provided on the resin in the through hole and its neighboring through-hole plating layer is formed on both surface sides of the substrate. Then, the partial cover plating layer is formed in the opening portion in the first resist by the plating. As a result, the pad is arranged in advance on the through hole.

Then, the first resist is removed, and then the second resist that covers the whole of the partial cover plating layer and has the pattern used to pattern the through-hole plating layer is formed. Then, the through-hole plating layer is patterned by the etching while using the second resist as a mask.

Accordingly, the pad wiring portion (the through hole pad) composed of the through-hole plating layer and the partial cover plating layer is formed on the through hole on both surface sides of the substrate, and the wiring pattern formed of the through-hole plating layer is formed separately from the pad wiring portion. The pad wiring portions on both surface sides of the substrate are connected mutually via the through-hole plating layer on the inner surface of the through hole.

In the present invention, the partial cover plating layer is formed only on the through hole on which the pad is arranged, but the cover plating layer is not formed on the through-hole plating layer acting as the wiring pattern. Therefore, unlike the prior art, there is no need to etch the thick cover plating layer, and the wiring pattern can be obtained by etching the through-hole plating layer having an optimum film thickness that meets the design request. Accordingly, since an etching shift caused in forming the wiring pattern can be considerably reduced, the fine wiring patterns can be formed.

In this manner, in the present invention, the thick pad wiring portion (the through hole pad) for covering the resin can be arranged on the resin in the through hole, and also the fine wiring pattern can be formed separately from the pad wiring portion.

Also, the present invention relates to method of manufacturing a wiring substrate, and includes the steps of forming a metal layer over a whole of a substrate; forming a first resist in which an opening portion is provided on the metal layer; forming a partial cover plating layer in the opening portion of the first resist by a plating; removing the first resist; forming a second resist which covers a whole of the partial cover plating layer and has a pattern for patterning the metal layer; and forming a wiring pattern, on a part of which the partial cover plating layer is provided upright, by etching the metal layer while using the second resist as a mask.

In the present invention, first, the metal layer is formed over the whole of the substrate, and then the first resist in which the opening portion is provided thereon is formed. Then, the partial cover plating layer is formed in the opening portion in the first resist by the plating, and then the first resist is removed. Then, the second resist that covers the whole of the partial cover plating layer and has the pattern used to pattern the metal layer is formed. Then, the wiring pattern on a part of which the partial cover plating layer is provided upright is formed by etching the metal layer while using the second resist as a mask.

The present invention has the technical idea common to the above invention. In this invention, the partial cover plating layer is formed previously on a part (the connection portion, or the like) of the metal layer, then the resist is patterned on the metal layer in a situation that the whole of the partial cover plating layer is covered with the resist, and then the metal layer is etched, whereby the wiring pattern on which the partial cover plating layer is provided upright is obtained. The partial cover plating layer that is provided upright from the connection portion of the wiring pattern functions as the via post or the connection pad.

In the present invention, the wiring pattern having the partial cover plating layer acting as the via post or the connection pad can be formed easily. Also, the wiring patterns whose film thicknesses are different in the identical wiring can be formed.

When the partial cover plating layer is utilized as the via post, the insulating layer for filling the via post is formed on the wiring pattern, and then an upper surface of the via post is exposed by polishing the insulating layer. Then, the upper wiring pattern connected to the via post is formed on the insulating layer.

As described above, according to the present invention, the pad wiring portions can be arranged on the through holes of the substrate, and also the fine wiring patterns can be formed.

### BRIEF DESCRIPTION OF THE DRAWINGS

FIGS. 1A to 1G are sectional views showing a method of manufacturing a wiring substrate in the prior art;

FIGS. 2A to 2N are sectional views showing a method of manufacturing a wiring substrate of a first embodiment of the present invention;

FIGS. 3A to 3I are sectional views showing a method of manufacturing a wiring substrate of a second embodiment of the present invention; and

FIGS. 4A to 4H are sectional views showing a method of manufacturing a wiring substrate of a third embodiment of the present invention.

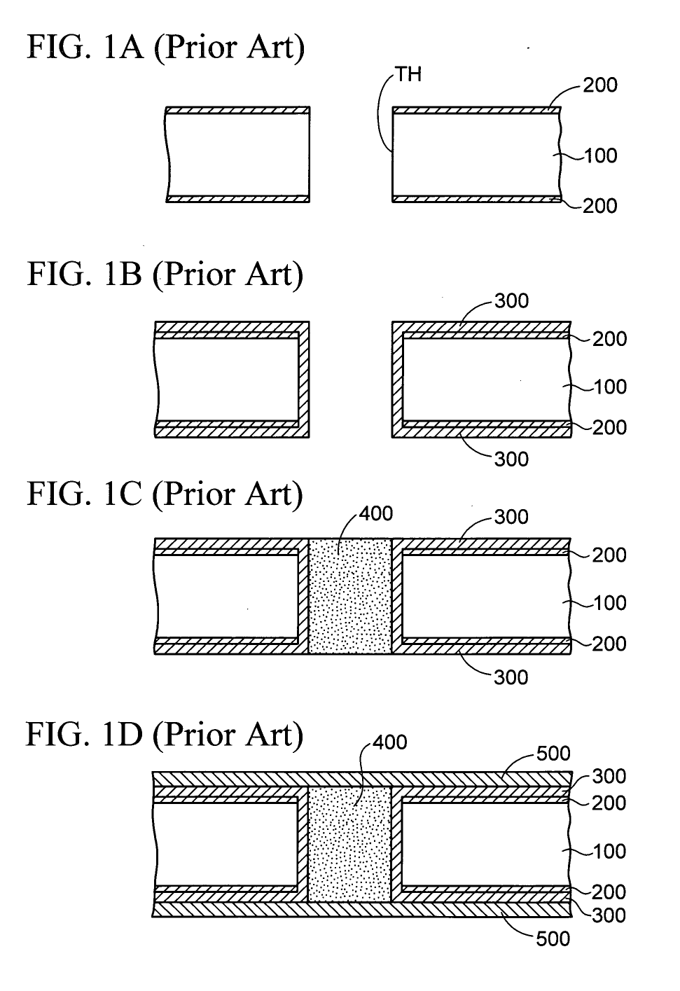

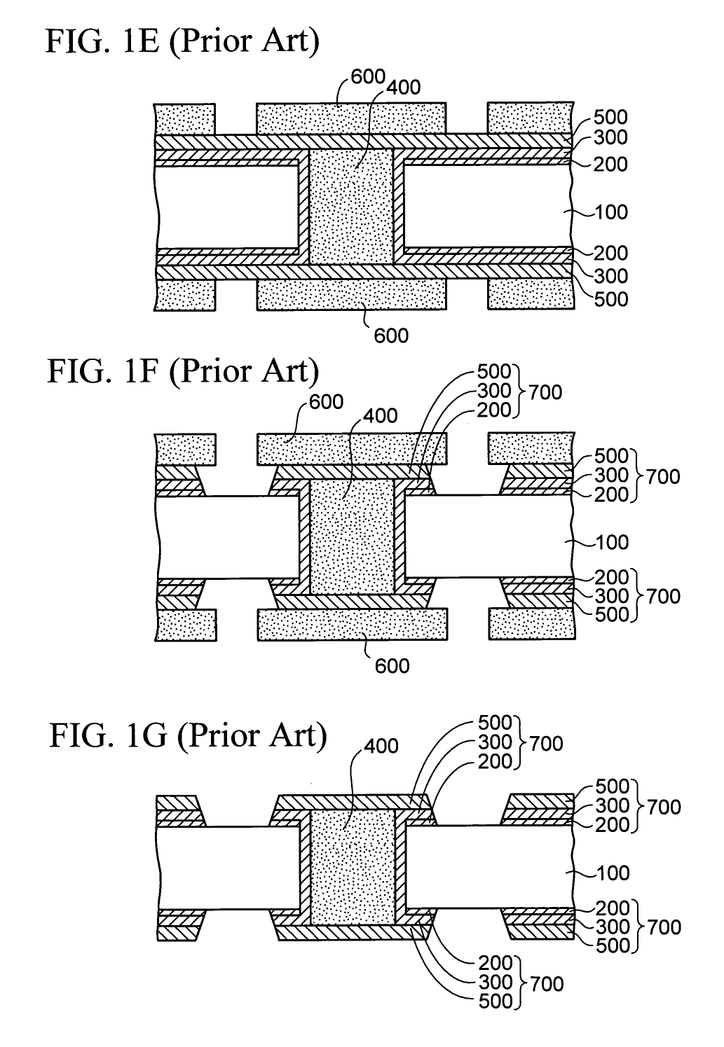

### DETAILED DESCRIPTION OF THE PREFERRED EMBODIMENTS

Embodiments of the present invention will be explained with reference to the accompanying drawings hereinafter.

### First Embodiment

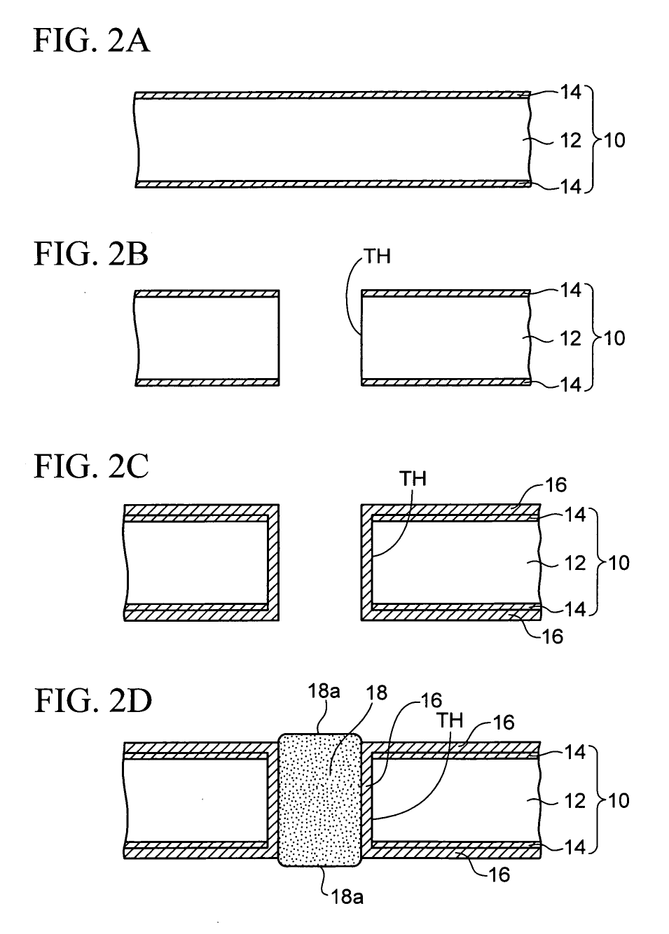

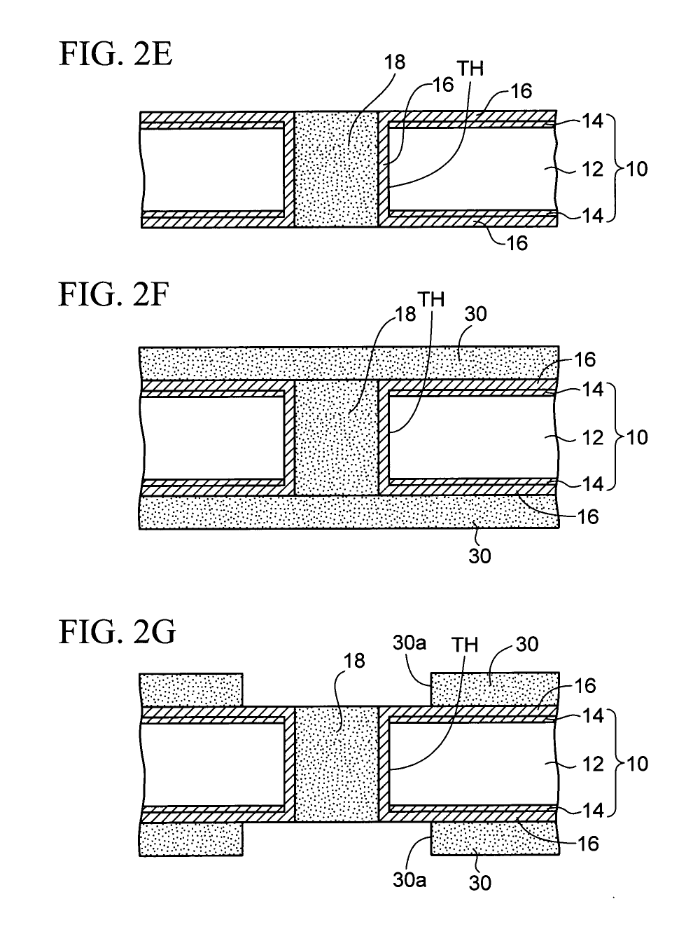

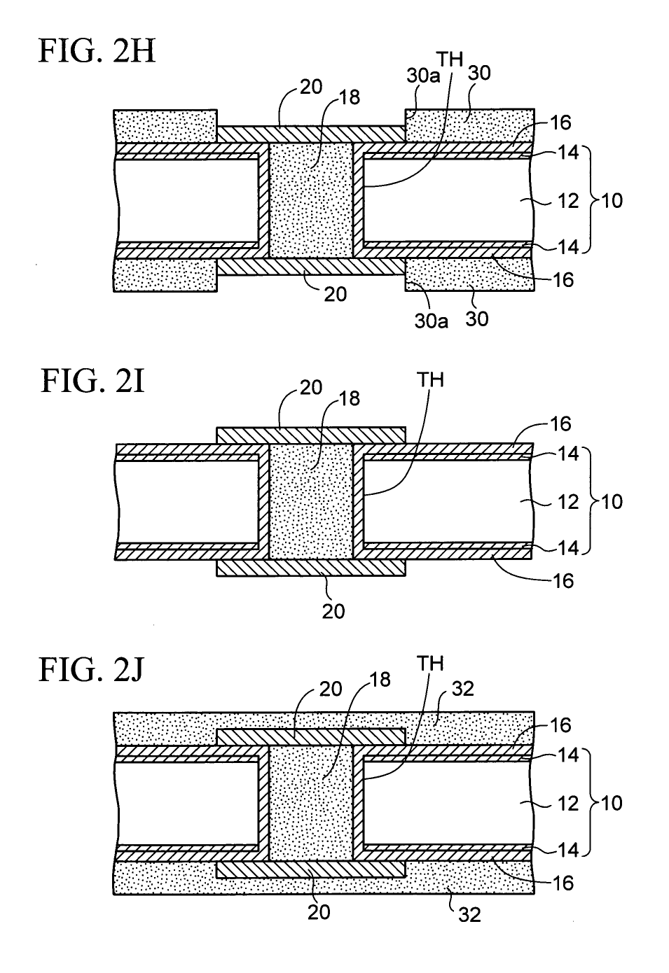

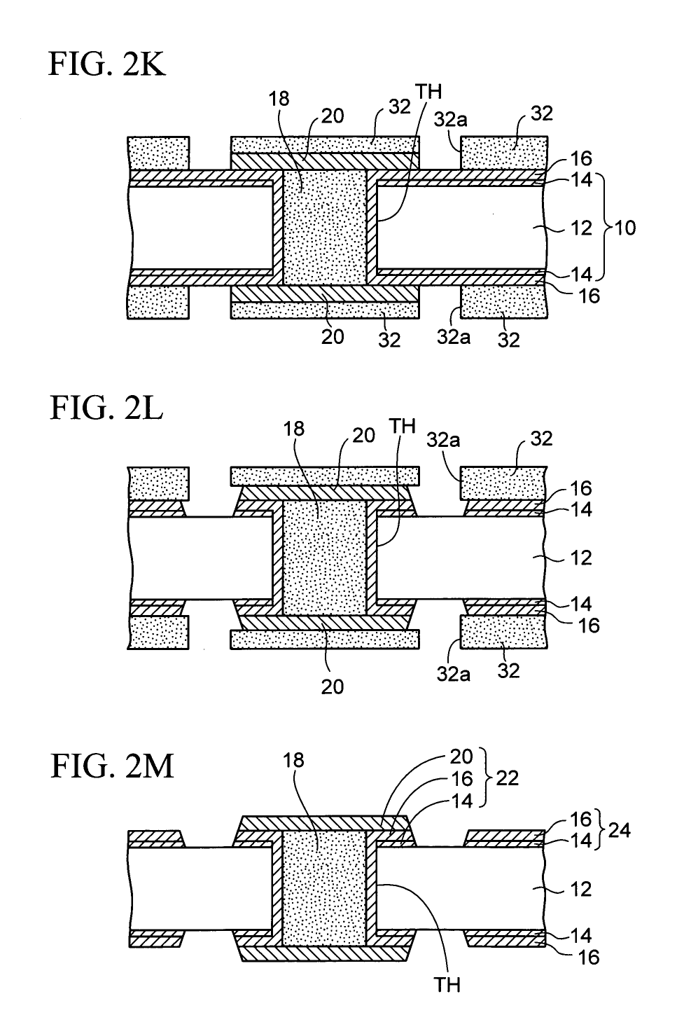

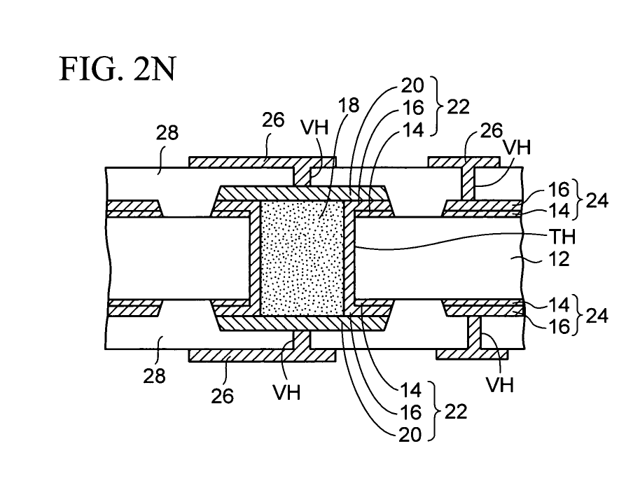

FIGS. 2A to 2N are sectional views showing a method of manufacturing a wiring substrate of a first embodiment of the present invention.

In the method of manufacturing a wiring substrate of the first embodiment of the present invention, as shown in FIG. 2A, first, a double-sided copper-clad laminate 10 having such a structure that a copper foil 14 is pasted on both surfaces of a resin substrate 12 is prepared. A thickness of the copper foil 14 is set to 5 to 20 μm, for example. Then, as shown in FIG. 2B, a through hole TH is formed by penetration-processing the double-sided copper-clad laminate 10 by a drill.

Then, as shown in FIG. 2C, a seed layer (not shown) made of copper, or the like is formed on both surface sides of the double-sided copper-clad laminate 10 and an inner surface of the through hole TH by the electroless plating, and then a metal layer (not shown) made of copper, or the like is formed on the seed layer by the electroplating utilizing a power feeding path as the seed layer. Thus, a through-hole plating layer 16 composed of the seed layer and the metal layer is obtained. The through-hole plating layer 16 is formed such that this layer is connected from the inner surface of the through hole TH onto the copper foil 14 on both surface sides of the double-sided copper-clad laminate 10 respectively. Also, a film thickness of the through-hole plating layer 16 is set to about 20 μm, for example.

Then, as shown in FIG. 2D, a hole filling resin 18 is filled in the through hole TH. At this time, the hole filling resin 18 is formed in a state that a projection portion 18a is projected from both surfaces of the double-sided copper-clad laminate 10 respectively. Then, as shown in FIG. 2E, the projection portion 18a of the hole filling resin 18 projected from both surfaces of the double-sided copper-clad laminate 10 respectively is polished by the grinder.

As a result, an upper surface and a lower surface of the hole filling resin 18 are planarized to constitute substantially coplanar surfaces to an upper surface and a lower surface of the through-hole plating layer 16. In polishing the projection portion 18a of the hole filling resin 18, the through-hole plating layer 16 on both surface sides is also polished to reduce its thickness. In case a film thickness of the through-hole plating layer 16 formed in the step in FIG. 2C is 20 μm, such film thickness is reduced to about 11 μm.

Then, as shown in FIG. 2F, a photosensitive first dry film resist 30 is formed on both surface sides of the double-sided copper-clad laminate 10 respectively. Then, as shown in FIG. 2G, the first dry film resist 30 on both surface sides is exposed/developed. Thus, an opening portion 30a is formed in an area, which corresponds to the through hole TH and its neighborhood, of the first dry film resist 30 on both surface sides respectively. In this case, a liquid resist may be coated instead of the first dry film resist 30.

Then, as shown in FIG. 2H, a seed layer (not shown) is formed on the hole filling resin 18 and the through-hole plating layer 16 in the opening portion 30a of the first dry film resist 30 on both surface sides of the double-sided copper-clad laminate 10 by the electroless plating. Then, a metal layer (not shown) is formed on the seed layer by the electroplating utilizing the seed layer and the through-hole plating layer 16 as a plating power feeding path. Accordingly, a partial cover plating layer 20 having a film thickness of about 12 μm, composed of the seed layer and the metal layer, and formed of copper and the like, is formed in the opening portion 30a of the first dry film resist 30 on both surface sides of the double-sided copper-clad laminate 10 respectively. Then, the first dry film resist 30 is removed.

As shown in FIG. 2I, the partial cover plating layer 20 on both surface sides of the double-sided copper-clad laminate 10 is formed to be patterned like a pad on the hole filling resin 18 in the through hole TH and its neighboring area of the through-hole plating layer 16, in a state that the partial cover plating layer 20 is connected electrically to the through-hole plating layer 16.

Then, as shown in FIG. 2J, a photosensitive second dry film resist 32 for covering the partial cover plating layer 20 and the through-hole plating layer 16 is formed on both surface sides of the double-sided copper-clad laminate 10 respectively. Then, as shown in FIG. 2K, the second dry film resist 32 is exposed/developed, and thus the second dry film resist 32 is patterned on both surface sides respectively. At this time, the second dry film resist 32 is patterned such that the whole of the partial cover plating layer 20 is covered with it, and the opening portion 32a for obtaining wiring patterns on the through-hole plating layer 16 is formed.

Then, as shown in FIG. 2L, the through-hole plating layer 16 and the copper foil 14 are etched by the wet etching using the chemical solution while using the second dry film resist 32 as a mask. Then, the second dry film resist 32 is removed. Thus, as shown in FIG. 2M, a pad wiring portion 22 composed of the copper foil 14, the through-hole plating layer 16, and the partial cover plating layer 20 is formed on the through hole TH and its neighborhood on both surface sides of the resin substrate 12 respectively. The pad wiring portions 22 formed on both surface sides of the resin substrate 12 are connected mutually via the through-hole plating layer 16 in the through hole TH.

At the same time, a wiring pattern 24 composed of the copper foil 14 and the through-hole plating layer 16 is formed on both surface sides of the resin substrate 12. The wiring pattern 24 is formed away from the pad wiring portions 22.

The pad wiring portions 22 may be formed as the through-hole pad that is formed in isolation like an island on the through hole TH. Otherwise, the partial cover plating layer 20 (pad) may be connected to another wiring pattern different from the wiring pattern 24 by extending the copper foil 14 and the through-hole plating layer 16 outwardly from an underlying area of the partial cover plating layer 20 (pad).

In the present embodiment, the partial cover plating layer 20 is formed only on the through hole TH and its neighborhood like a pad, but the partial cover plating layer is not formed in the area on the through-hole plating layer 16 where the wiring pattern 24 is arranged. Therefore, in the above steps of forming the pad wiring portion 22 and the wiring pattern 24 in FIGS. 2K and 2L, unlike the prior art, there is no need to etch the cover plating layer formed of a thick film whose thickness is 12 μm, for example, as a result the wiring pattern 24 can be obtained by etching only the through-hole plating layer 16 and the copper foil 14.

For example, a total film thickness of the copper foil 14 and the through-hole plating layer 16 is thinned to about 11 μm after the hole filling resin 18 is polished (FIG. 2E). Therefore, an etching shift can be reduced considerably rather than the case where both layers together with the cover plating layer are wet-etched. When the approach of the present embodiment is employed, the partial cover plating layer 20 (the through-hole pad) for covering the hole filling resin 18 can be arranged on the hole filling resin 18 in the through hole TH and also the wiring pattern 24 can be formed easily in the line width specification in which a line and a space is less than 40 μm:40 μm.

Also, in the present embodiment, a film thickness of the wiring pattern 24 can be adjusted by controlling respective film thicknesses of the copper foil 14 and the through-hole plating layer 16 in a situation that the cover plating layer is not formed in the area where the wiring pattern 24 is formed. Therefore, the wiring pattern 24 does not unnecessarily become thick, and the fine patterning can be carried out. In this manner, the wiring pattern 24 can be formed to have the appropriate line width and film thickness in view of the etching shift and the wiring resistance to each film thickness.

Then, as shown in FIG. 2N, an interlayer insulating layer 28 is formed by pasting a resin film, or the like on the pad wiring portion 22 and the wiring pattern 24 on both surface sides of the resin substrate 12 respectively. Then, via holes VH reaching the pad wiring portion 22 and the wiring pattern 24 are formed in the interlayer insulating layer 28 on both surface sides respectively. Then, upper wiring patterns 26 connected to the pad wiring portion 22 and the wiring pattern 24 via the via hole VH are formed on the interlayer insulating layer 28 on both surface sides of the resin substrate 12 respectively.

In this manner, n-layered (n is an integer of 1 or more) wiring patterns connected to the pad wiring portion 22 and the wiring pattern 24 are stacked on both surface sides of the resin substrate 12 respectively. Thus, the wiring substrate of the first embodiment is obtained.

As shown in FIG. 2N, in the wiring substrate of the first embodiment, the through hole TH is provided in the resin substrate 12, and the hole filling resin 18 is filled in the through hole TH. The through-hole plating layer 16 shaped into the pattern is formed to extend from an area between the inner surface of the through hole TH and the hole filling resin 18 to both surfaces of the resin substrate 12 respectively. The copper foil 14 is formed to be patterned under the through-hole plating layer 16 on both surface sides of the resin substrate 12.

Also, the partial cover plating layer 20 is formed on the hole filling resin 18 in the through hole TH and the through-hole plating layer 16 in neighborhood of the hole filling resin 18 on both surface sides of the resin substrate 12 respectively. In this way, the pad wiring portion 22 is composed of the copper foil 14, the through-hole plating layer 16, and the partial cover plating layer 20. The partial cover plating layers 20 of the pad wiring portions 22 on both surface sides are connected mutually via the through-hole plating layer 16 on the inner surface of the through hole TH.

Also, the wiring pattern 24 that is composed of the copper foil 14 and the through-hole plating layer 16 and is separated from the pad wiring portion 22 is formed on both surface sides of the resin substrate 12 respectively. The wiring pattern 24 is formed by patterning the same stacked films as the copper foil 14 and the through-hole plating layer 16 constituting a part of the pad wiring portion 22. Since the wiring pattern 24 is formed not to include the partial cover plating layer, its film thickness is set thinner than that of the pad wiring portion 22.

In this case, in the present embodiment, the double-sided copper-clad laminate 10 is used as the substrate, but an insulating substrate onto which the copper foil is not pasted may be used. In the case of this mode, the pad wiring portion 22 is composed of the through-hole plating layer 16 and the partial cover plating layer 20, and the wiring pattern 24 is formed only of the through-hole plating layer 16.

Also, the interlayer insulating layer 28 in which the via holes VH reaching the pad wiring portion 22 and the wiring pattern 24 are formed is formed on both surface sides of the resin substrate 12 respectively. Also, the upper wiring pattern 26, which is connected to the pad wiring portion 22 and the wiring pattern 24 via the via hole VH, is formed on the interlayer insulating layer 28 on both surface sides of the resin substrate 12 respectively. In this way, the n-layered (n is an integer of 1 or more) wiring patterns connected to the pad wiring portion 22 and the wiring pattern 24 are stacked on them on both surface sides of the resin substrate 12 respectively. Thus, the wiring substrate of the first embodiment is obtained.

The partial cover plating layer 20 of the pad wiring portion 22 for coating the through hole TH serves as the through-hole pad that connects the pad wiring portions 22 which are connected mutually via the through-hole plating layer 16, to the upper wiring pattern 26 with good reliability. Then, the electronic component (the semiconductor chip, or the like) is mounted on the connection portions of the wiring patterns exposed from an uppermost area on one surface side of the resin substrate 12, while external connection terminals are provided on the connection portions of the wiring patterns exposed from an uppermost area on the other surface side of the resin substrate 12.

In this manner, in the wiring substrate of the first embodiment, the pad wiring portion 22 serving as the through-hole pad can be arranged on the through hole TH and also the wiring pattern 24 can be formed in an optimum film thickness not to contain the cover plating layer. Therefore, the wiring pattern 24 can be formed in the required line width specification.

### Second Embodiment

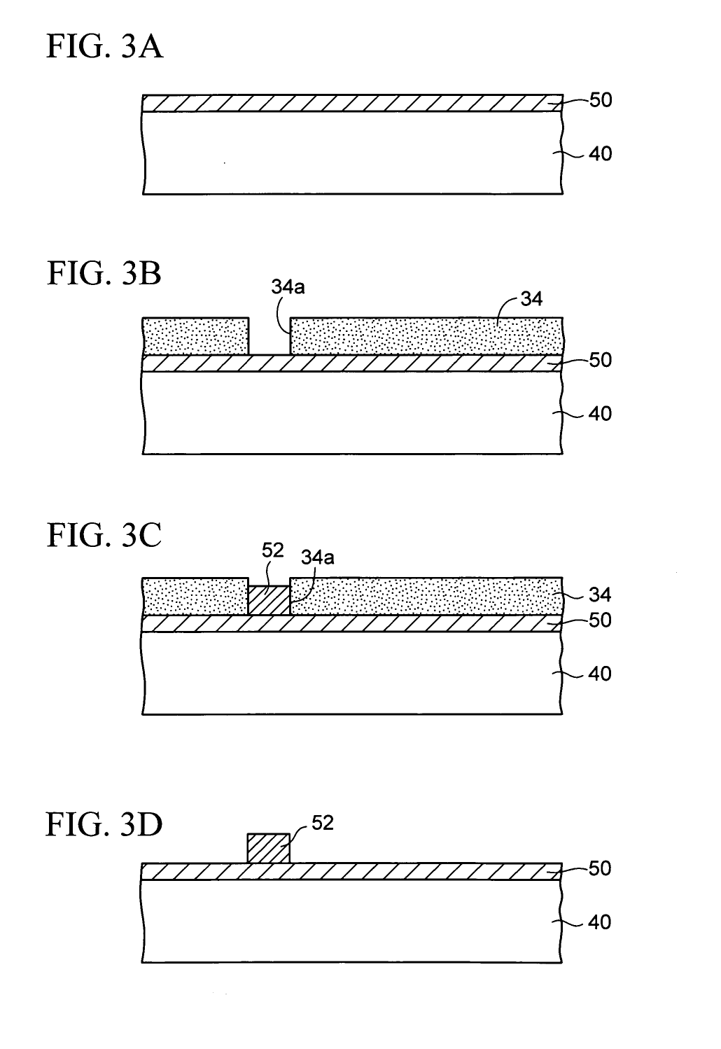

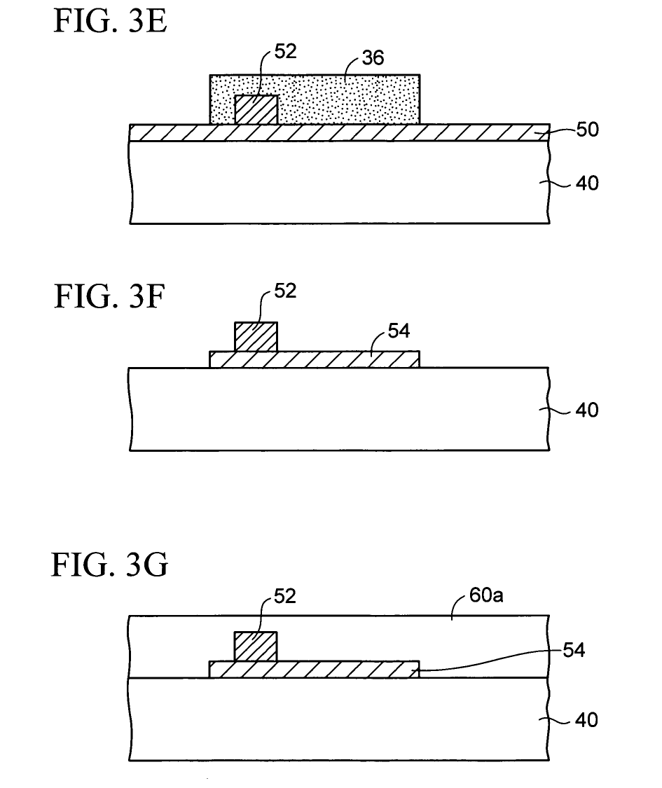

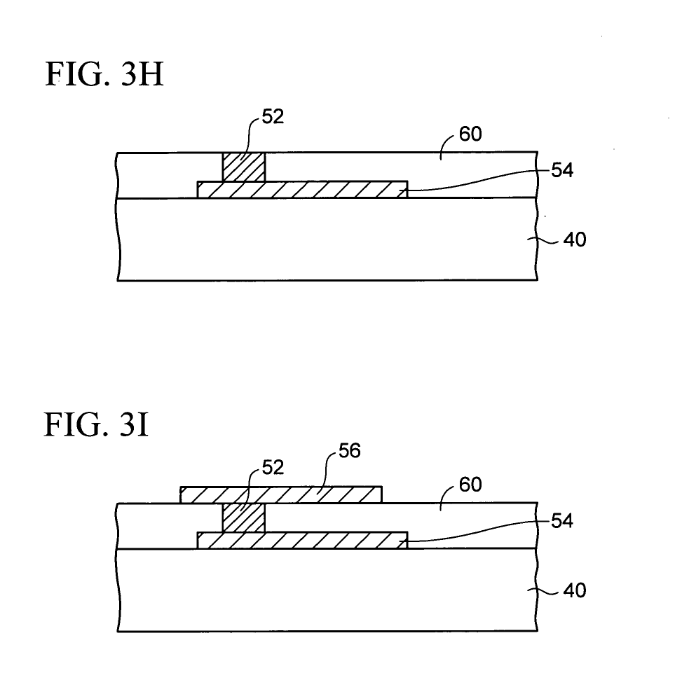

FIGS. 3A to 3I are sectional views showing a method of manufacturing a wiring substrate of a second embodiment of the present invention.

A feature of the second embodiment resides in that via posts of the multi-layered wirings are formed by utilizing the method of manufacturing the wiring substrate of the present invention. In the second embodiment, detailed explanation of the same steps as those in the first embodiment will be omitted herein.

As shown in FIG. 3A, first, a structure in which a metal layer 50 made of copper, or the like is provided over the whole of an insulating substrate 40 is prepared. The metal layer 50 may be used to form halfway wirings in forming the multi-layered wiring on the substrate 40. In such case, the metal layer 50 is formed on a predetermined interlayer insulating layer.

Then, as shown in FIG. 3B, a first dry film resist 34 in which an opening portion 34a is provided in a portion of the metal layer 50, in which a via post is formed, is formed by the similar method to that in the first embodiment. Then, as shown in FIG. 3C, a metal plating layer made of copper, or the like is formed in the opening portion 34a of the first dry film resist 34 by the electroplating utilizing the metal layer 50 as a plating power feeding path. Thus, a via post 52 is obtained in the opening portion 34a of the first dry film resist 34.

Then, as shown in FIG. 3D, the via post 52 is exposed by removing the first dry film resist 34.

Then, as shown in FIG. 3E, a second dry film resist 36 in which a pattern to form the wiring pattern is provided is formed on the area on the metal layer 50, the area that covers the whole of the via post 52. Then, the metal layer 50 is etched by using the second dry film resist 36 as a mask, and then the second dry film resist 36 is removed.

Thus, as shown in FIG. 3F, a wiring pattern 54 in which the via post 52 is provided upright on the connection portion is formed on the substrate 40. A height of the via post 52 is set to correspond to an interlayer thickness of the multi-layered wiring. At this time, the wiring pattern to which the via post 52 is not connected may be formed simultaneously.

Then, as shown in FIG. 3G, an insulating layer 60a is formed on the via post 52 and the wiring pattern 54 by method to paste a resin film thereon, or the like. Then, as shown in FIG. 3H, the insulating layer 60a is polished until an upper surface of the via post 52 is exposed. Thus, an interlayer insulating layer 60 is left on the side of the via post 52. As a result, an upper surface of the via post 52 and an upper surface of the interlayer insulating layer 60 are planarized to constitute the substantially coplanar surface.

Thus, as shown in FIG. 3I, an upper wiring pattern 56 connected to the wiring pattern 54 via the via post 52 is formed on the interlayer insulating layer 60.

In this manner, in the second embodiment, the first dry film resist 34 in which the opening portion 34a is provided in the portion that acts as the connection portion on the metal layer 50 is formed, and the via post 52 is formed in the opening portion 34a by the electroplating. Then, the first dry film resist 34 is removed, and then the second dry film resist 36 is patterned to get the wiring pattern that is connected to the via post 52. Then, the wiring pattern 54 on which the via post 52 is provided upright can be formed easily by etching the metal layer 50 while using the second dry film resist 36 as a mask.

Since the via post 52 is provided upright to the connection portion of the wiring pattern 54, the step of forming the via hole and the step of burying a conductor in the via hole can be omitted, and thus a production cost can reduced.

In the second embodiment, the n-layered (n is an integer of 1 or more) wiring patterns connected to the wiring pattern 54 may also be stacked by repeating the similar steps.

### Third Embodiment

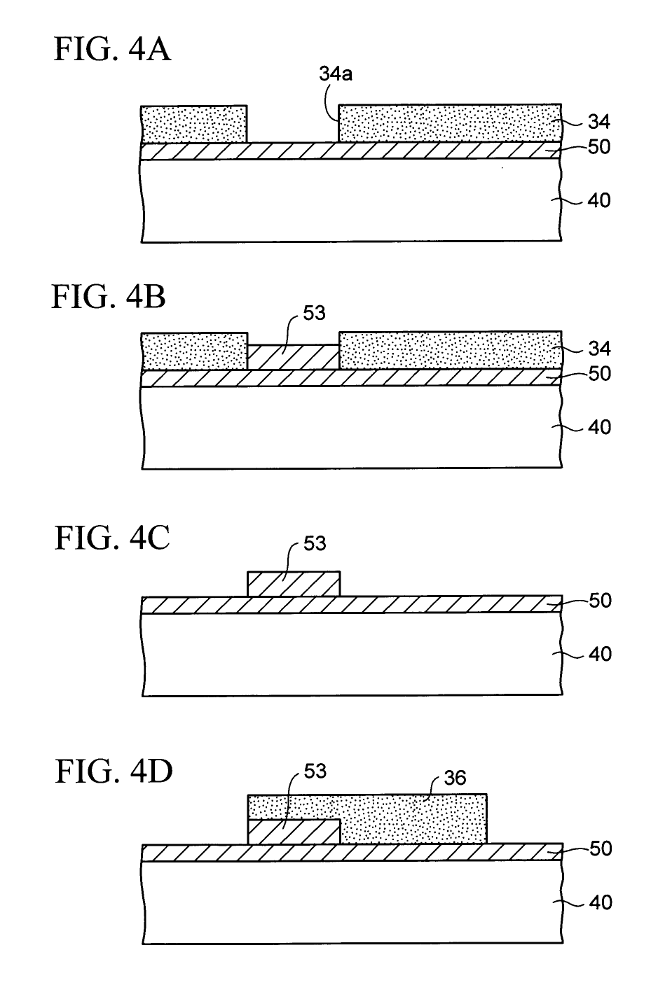

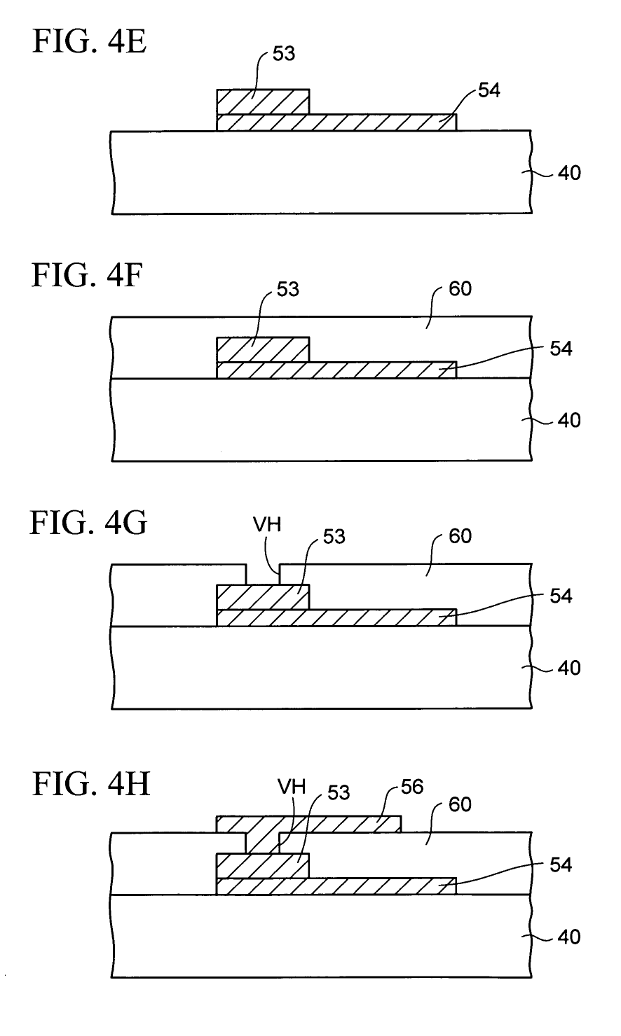

FIGS. 4A to 4H are sectional views showing a method of manufacturing a wiring substrate of a third embodiment of the present invention.

A feature of the third embodiment resides in that the wiring pattern on which the connection pad is provided upright is formed by utilizing the method of manufacturing the wiring substrate of the present invention. In the third embodiment, detailed explanation of the same steps as those in the first embodiment will be omitted herein.

In the third embodiment, as shown in FIG. 4A, like the second embodiment, first, the structure in which the metal layer 50 is formed over the whole of the substrate 40 is prepared. Then, the first dry film resist 34 in which the opening portion 34a is provided in the area of the metal layer 50 where the connection pad is arranged is formed. Then, as shown in FIG. 4B, a metal plating layer is formed in the opening portion 34a of the first dry film resist 34 by the electroplating utilizing the metal layer 50 as a plating power feeding path. Thus, a connection pad 53 is obtained in the opening portion 34a of the first dry film resist 34.

As the connection pad 53, a single film of a nickel (Ni) layer, a palladium (Pd) layer, a tin (Sn) layer, or a gold (Au) layer or a laminated film formed of two layers or more selected from these layers may be utilized, in addition to a copper (Cu) layer. Then, as shown in FIG. 4C, the connection pad 53 is exposed by removing the first dry film resist 34.

Then, as shown in FIG. 4D, a second dry film resist 36 in which a pattern to form the wiring pattern is provided is formed on the area on the metal layer 50, the area that covers the whole of the connection pad 53. Then, the metal layer 50 is etched by using the second dry film resist 36 as a mask, and then the second dry film resist 36 is removed.

Thus, as shown in FIG. 4E, the wiring pattern 54 on which the connection pad 53 is provided upright is formed on the substrate 40. At this time, the wiring pattern to which the connection pad 53 is not connected may be formed simultaneously.

Then, as shown in FIG. 4F, the interlayer insulating layer 60 for covering the connection pad 53 and the wiring pattern 54 is formed on the substrate 40. Then, as shown in FIG. 4G, the via hole VH reaching the connection pad 53 is formed by processing the interlayer insulating layer 60 by means of the laser. At this time, even when a film thickness of the wiring pattern 54 is set thin to enable the fine patterning, such disadvantages can be avoided that the via hole VH passes through the wiring pattern 54 in forming this via hole VH, and the like because the connection pad 53 is provided on the connection portion of the wiring pattern 54.

Then, as shown in FIG. 4H, the upper wiring pattern 56 connected to the connection pad 53 of the wiring pattern 54 via the via hole VH is formed on the interlayer insulating layer 60.

In the third embodiment, the n-layered (n is an integer of 1 or more) wiring patterns connected to the wiring pattern 54 may also be stacked.

In the second and third embodiments, the mode where the wiring pattern on the connection portion of which the via post or the connection pad is provided upright is formed is illustrated. In this case, the wiring patterns whose film thicknesses are different can be formed in the identical wiring.

What is claimed is:

1. A method of manufacturing a wiring substrate, comprising the steps of:
forming a through hole in a substrate;
forming a through-hole plating layer from an inner surface of the through hole to both surface sides of the substrate;
filling a resin in the through hole;
forming a first resist, in which an opening portion is provided on the through hole and its neighborhood, on both surface sides of the substrate respectively;
forming a partial cover plating layer connected to the through-hole plating layer of the opening portion in the first resist by a plating;
removing the first resist;
forming a second resist, which covers a whole of the partial cover plating layer and has a pattern for patterning the through-hole plating layer, on both surface sides of the substrate respectively; and
forming a pad wiring portion, which is composed of the through-hole plating layer and the partial cover plating layer and connected mutually via the through-hole plating layer, and a wiring pattern, which is formed of the through-hole plating layer and separated from the pad wiring portion, on both surface sides of the substrate respectively, by etching the through-hole plating layer while using the second resist as a mask.

2. A method of manufacturing a wiring substrate according to claim 1, wherein the substrate is a double-sided copper-clad laminate in which a copper foil is pasted on both surface sides of a resin substrate,
in the step of etching the through-hole plating layer, the copper foil under the through-hole plating layer is further etched,
the pad wiring portion and the wiring pattern are respectively composed by forming further the copper foil under the through-hole plating layer.

3. A method of manufacturing a wiring substrate according to claim 1, after the step of forming the pad wiring portion and the wiring pattern, further comprising the step of:
stacking n-layered (n is an integer of 1 or more) wirings connected to the pad wiring portion and the wiring pattern respectively.

4. A method of manufacturing a wiring substrate, comprising the steps of:
forming a metal layer over a whole of a substrate;
forming a first resist in which an opening portion is provided on the metal layer;
forming a partial cover plating layer in the opening portion of the first resist by a plating;
removing the first resist;
forming a second resist which covers a whole of the partial cover plating layer and has a pattern for patterning the metal layer; and
forming a wiring pattern, on a part of which the partial cover plating layer is provided upright, by etching the metal layer while using the second resist as a mask.

5. A method of manufacturing a wiring substrate according to claim 4, wherein the partial cover plating layer is a via post for interlayer connection, and
after the step of forming the wiring pattern, further comprising the steps of:
forming an insulating layer on the wiring pattern;
polishing the insulating layer to expose an upper surface of the via post; and
forming an upper wiring pattern connected to the via post on the insulating layer.

6. A method of manufacturing a wiring substrate according to claim 4, wherein the partial cover plating layer is a connection pad of the wiring pattern, and
after the step of forming the wiring pattern, further comprising the steps of:
forming an insulating layer on the wiring pattern;
forming a via hole reaching the connection pad, by processing the insulating layer; and
forming an upper wiring pattern connected to the connection pad via the via hole on the insulating layer.

7. A wiring substrate, comprising:
a substrate in which a through hole is provided;
a resin filled in the through hole;
a pad wiring portion composed of a through-hole plating layer which is patterned, and is formed to extend from an area between an inner surface of the through hole and the resin to both surface sides of the substrate respectively, and a partial cover plating layer having pad-like shape, which is formed on the resin in the through hole and the through-hole plating layer on both surface sides of the substrate respectively; and
a wiring pattern formed of an identical layer as the through-hole plating layer and patterned on both surface sides of the substrate respectively such that the wiring pattern is separated from the pad wiring portion;
wherein the pad wiring portions on both surface sides of the substrate are connected mutually via the through-hole plating layer, and a film thickness of the wiring pattern is set thinner than a film thickness of the pad wiring portion.

8. A wiring substrate according to claim 7, wherein the pad wiring portion and the wiring pattern formed on both surface sides of the substrate are respectively composed to contain a patterned copper foil under the through-hole plating layer.

9. A wiring substrate according to claim 7, further comprising:
an insulating layer which is formed on the pad wiring portion and the wiring pattern on both surface sides of the substrate respectively, and in which a via hole is provided on the pad wiring portion on the through hole and on the wiring pattern respectively; and
an upper wiring pattern formed on the insulating layer on both surface sides of the substrate respectively, and connected to the pad wiring portion and the wiring pattern via the via hole.
